(19) United States
(12) Patent Application Publication
(10) Pub. No.: US 2014/0306123 A1
(43) Pub. Date: Oct. 16, 2014

(54) STAGE APPARATUS, DRAWING APPARATUS, AND METHOD OF MANUFACTURING ARTICLE

(71) Applicant: CANON KABUSHIKI KAISHA, Tokyo (JP)

(72) Inventors: Tomonori ISHIKAWA, Utsunomiya-shi (JP); Shinji UCHIDA, Utsunomiya-shi (JP)

(73) Assignee: CANON KABUSHIKI KAISHA, Tokyo (JP)

(21) Appl. No.: 14/220,684

(22) Filed: Mar. 20, 2014

(30) Foreign Application Priority Data
Apr. 16, 2013 (JP) 2013-086059

(51) Int. Cl. H01J 37/20; H01J 37/317

(52) U.S. Cl. CPC H01J 37/20; H01J 37/3174
USPC 250/453.11

(57) ABSTRACT

A stage apparatus includes: a stage; a linear motor configured to drive the stage; a magnetic shield unit configured to surround the linear motor to shield a magnetic field generated by a magnet of the linear motor; and a degaussing coil located in a space surrounded by the magnetic shield unit and configured to degauss the magnetic shield unit.

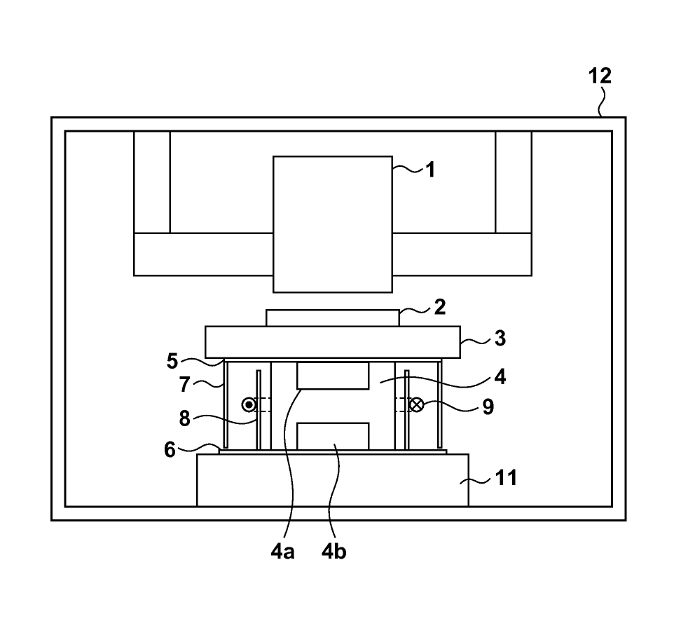

### BACKGROUND OF THE INVENTION

1. Field of the Invention

The present invention relates to a stage apparatus, a drawing apparatus, and a method of manufacturing an article.

2. Description of the Related Art

An electron beam drawing apparatus (electron beam exposure apparatus) includes an electron gun, electron optical system, deflector, stage, and magnetic-field shield. The electron gun generates an electron beam. The electron optical system converges the electron beam generated by the electron gun onto a substrate. The deflector positions the electron beam on the substrate at high accuracy. The stage moves the substrate with respect to the electron beam. A peripheral device is, for example, an electric rack in which substrates are stored to control an electron beam. The magnetic-field shield shields variations of the magnetic field generated from the peripheral device. The electron beam drawing apparatus draws a target pattern on the substrate by synchronizing the electron beam positioned by the deflector and the movement of the stage.

The stage which moves a substrate includes a coarse moving stage having a long stroke to irradiate the entire surface of a substrate with an electron beam, and a fine moving stage having a short stroke to finely position a substrate. Positioning by the fine moving stage uses a linear motor constituted by a movable element (magnet) and stator (coil). Japanese Patent Laid-Open No. 2004-55767 discloses a method of attaching a multiple electromagnetic shield to a linear motor by using a permalloy or the like in order to prevent the magnet of the linear motor from causing variations of the magnetic field.

Japanese Patent Laid-Open No. 2003-37047 discloses a linear motor for driving a coarse moving stage. The linear motor in Japanese Patent Laid-Open No. 2003-37047 includes a magnetic shield for shielding a magnetic field from a magnet, and an electromagnetic coil which is located near the opening of the magnetic shield outside the magnetic shield to cancel a magnetic field leaking from the opening.

If a shock is applied to the fine moving stage owing to emergency stop or the like, a stress is locally applied even to the shield unit of the linear motor for positioning the fine moving stage, and the shield unit is sometimes magnetized. The magnetization of the shield unit degrades the drawing accuracy of an electron beam. If the electromagnetic coil is located outside the shield unit to eliminate the magnetization, it may magnetize a magnetic material around an electron beam, such as a magnetic material in the electron optical system barrel (electron optical system housing; vacuum chamber), degrading the drawing accuracy of the electron beam.

### SUMMARY OF THE INVENTION

The present invention provides a stage apparatus which reduces leakage of magnetism. The present invention provides a stage apparatus comprising: a stage; a linear motor configured to drive the stage; a magnetic shield unit configured to surround the linear motor to shield a magnetic field generated by a magnet of the linear motor; and a degaussing coil located in a space surrounded by the magnetic shield unit and configured to degauss the magnetic shield unit.

Further features of the present invention will become apparent from the following description of exemplary embodiments with reference to the attached drawings.

### BRIEF DESCRIPTION OF THE DRAWINGS

FIGURE is a view showing the schematic arrangement of a drawing apparatus according to the present invention.

### DESCRIPTION OF THE EMBODIMENTS

FIGURE is a view showing the schematic arrangement of a drawing apparatus which performs drawing on a substrate by using an electron beam as a charged particle beam. Although the electron beam is used as a charged particle beam in the embodiment, a charged particle beam other than the electron beam, such as an ionic line, is usable. The drawing apparatus includes an electron optical system (charged particle optical system) 1 which generates an electron beam to irradiate a substrate 2, a fine moving stage 3, a coarse moving stage 11, a linear motor 4 which drives the fine moving stage 3, and a vacuum chamber 12 which stores them.

The linear motor 4 includes a movable element (magnet) 4a and stator (coil) 4b. The movable element 4a is held on a surface (lower surface) of the fine moving stage 3 on the side of the linear motor 4. The stator 4b is supported on a surface (upper surface) of the coarse moving stage 11 on the side of the linear motor 4. In the embodiment, the fine moving stage 3 constitutes a stage which holds the substrate 2, and the coarse moving stage 11 constitutes a supporting member which supports the stator 4b of the linear motor 4. In the embodiment, the stage apparatus has a coarse and fine arrangement using the fine moving stage 3 and coarse moving stage 11. However, the stage apparatus according to the present invention is not limited to the coarse and fine arrangement. In this case, the stage 3 holds the movable element 4a, and a supporting member such as a base supports the stator 4b.

The electron optical system 1 includes an electron gun which emits an electron beam, an aperture which splits the electron beam into a plurality of beams, a blanking deflector (blanker) which blanks the electron beam, and a scanning deflector which deflects and scans the electron beam having passed through the blanker. The fine moving stage 3 has a short substrate moving stroke, supports the substrate 2, and finely positions the substrate. The coarse moving stage 11 is longer in the moving stroke of the substrate 2 than the fine moving stage 3. The vacuum chamber 12 is constructed as a magnetically shielded room which prevents leakage of magnetism in the chamber to the outside of the chamber, or entrance of magnetism outside the chamber into the chamber.

The fine moving stage 3 supporting the substrate 2 mounts, on its upper surface, a substrate holder (not shown) which holds the substrate 2, and a mirror for measuring the position of the fine moving stage 3 in the left-and-right direction and a direction perpendicular to the sheet surface. The position of the fine moving stage 3 in the left-and-right direction is measured by, for example, a laser interferometer (not shown) installed in the vacuum chamber 12. The position of the fine moving stage 3 in the direction perpendicular to the sheet surface is similarly measured. Since the drawing apparatus operates in vacuum, the apparatus is kept in vacuum. The fine moving stage 3 is placed above the coarse moving stage 11 having a long stroke to move the substrate 2 on the entire surface. The fine moving stage 3 is configured to be movable at 6-axis degrees of freedom by the linear motor 4.

To shield a leak field generated from the linear motor 4, the linear motor 4 is covered with a plate-shaped first magnetic shield 5, plate-shaped second magnetic shield 6, tubular third magnetic shield 7, and tubular fourth magnetic shield 8. The first magnetic shield 5 is attached to the lower surface of the fine moving stage 3 to shield the influence of a magnetic field generated by the movable element (magnet) 4a of the linear motor 4 on the upper portion of the linear motor 4. The second magnetic shield 6 is attached to the upper surface of the coarse moving stage 11 to shield the influence of the magnetic field from the magnet of the linear motor 4 on the lower portion of the linear motor 4. The third magnetic shield 7 and fourth magnetic shield 8 are located to surround the linear motor 4 to shield the influence of the magnetic field from the magnet of the linear motor 4 on the side portion of the linear motor 4.

The first to fourth magnetic shields 5 to 8 may be magnetized owing to a mechanical distortion generated when a shock is applied to the fine moving stage 3 upon collision or the like. To degauss the magnetized first to fourth magnetic shields 5 to 8, a degaussing coil 9 is located in a space surrounded by the third magnetic shield 7 and the fourth magnetic shield. The degaussing coil 9 is an annular coil located to surround the linear motor 4, and its magnetic vector is the vertical direction (electron beam irradiation direction).

In the magnetic shield unit according to the embodiment, the third magnetic shield 7 is located outside the fourth magnetic shield 8 to surround the degaussing coil 9. In the embodiment, the third magnetic shield 7 and fourth magnetic shield 8 have a cylindrical shape surrounding the vertical magnetic vector of the degaussing coil 9. The third magnetic shield 7 surrounds the outer side of the degaussing coil 9, and the fourth magnetic shield 8 is located on the inner side of the degaussing coil 9. The first magnetic shield 5 and second magnetic shield 6 have a disk shape having an area larger than that of a circle formed by the periphery of the third magnetic shield 7 in order to prevent leakage of magnetism in the range of the moving stroke of the fine moving stage 3.

To degauss the magnetized first to fourth magnetic shields 5 to 8, a current of an AC attenuation waveform is supplied to the degaussing coil 9. Since the degaussing coil 9 is surrounded by the first to fourth magnetic shields 5 to 8, the magnetic field circulates on the inner side of the first magnetic shield 5, second magnetic shield 6, third magnetic shield 7, and fourth magnetic shield 8 upon supplying the degaussing current, and hardly leaks outside the magnetic shield unit. This can prevent the influence, on the electron beam irradiation path, of magnetization of a magnetic material contained in the electron optical system 1 owing to the current of the degaussing coil 9.

In the above description, the degaussing coil 9 has an annular shape, and the third and fourth magnetic shields 7 and 8 have a cylindrical shape. However, these shapes are arbitrary. The degaussing coil 9 may have a polygonal shape, and the third and fourth magnetic shields 7 and 8 may have a tubular shape whose periphery is defined by an arbitrary closed curve, such as a square tubular shape having a polygonal section. The first and second magnetic shields 5 and 6 suffice to be flat plates whose area is equal to or larger than the area of the closed curve of the periphery of the third magnetic shield 7.

In the embodiment, the first and third magnetic shields 5 and 7 are located on the fine moving stage 3, and the second and fourth magnetic shields 6 and 8 are located on the coarse moving stage 11. However, even these locations have the degree of freedom, and the third and fourth magnetic shields 7 and 8 may be arbitrarily located on the fine moving stage 3 or coarse moving stage 11. That is, the third magnetic shield 7 is attached to one of the fine moving stage 3 and coarse moving stage 11, and the fourth magnetic shield 8 is attached to the other one.

In the embodiment, the fourth magnetic shield 8 is interposed between the degaussing coil 9 and the linear motor 4. However, the third magnetic shield 7 surrounds the side of the space defined by the first and second magnetic shields 5 and 6 which surround the degaussing coil 9 and linear motor 4 from above and below them. Thus, the fourth magnetic shield 8 may be omitted.

### Method of Manufacturing Article

A method of manufacturing an article according to an embodiment of the present invention is suitable for manufacturing an article such as a semiconductor device or an original (which can also be called, for example, a reticle or mask). This manufacturing method can include a step of drawing a pattern on a photosensitive agent-applied substrate by using the above-described charged particle beam drawing apparatus, and a step of developing the substrate on which the pattern is drawn. Further, when manufacturing a device, the manufacturing method can include other well-known steps (for example, oxidization, deposition, vapor deposition, doping, planarization, etching, resist removal, dicing, bonding, and packaging).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefits of Japanese Patent Application No. 2013-086059, filed Apr. 16, 2013, which is hereby incorporated by reference herein in its entirety.

What is claimed is:

1. A stage apparatus comprising:
a stage;
a linear motor configured to drive said stage;
a magnetic shield unit configured to surround said linear motor to shield a magnetic field generated by a magnet of said linear motor; and
a degaussing coil located in a space surrounded by said magnetic shield unit and configured to degauss said magnetic shield unit.

2. The apparatus according to claim 1, wherein said degaussing coil includes an annular coil located to surround said linear motor.

3. The apparatus according to claim 1, further comprising a supporting member configured to support a stator of said linear motor,
wherein said stage holds a movable element of said linear motor on a surface on a side of said linear motor, and
said magnetic shield unit includes:
a plate-shaped first magnetic shield attached to the surface of said stage on the side of said linear motor;
a plate-shaped second magnetic shield attached to a surface of said supporting member on a side of said linear motor; and
a tubular third magnetic shield attached to one of said stage and said supporting member to surround said linear motor and said degaussing coil.

4. The apparatus according to claim 3, wherein said magnetic shield unit further includes a tubular fourth magnetic shield located between said degaussing coil and said linear motor to surround said linear motor.

5. The apparatus according to claim 4, wherein the third magnetic shield is attached to one of said stage and said supporting member, and the fourth magnetic shield is attached to the other one of said stage and said supporting member.

6. The apparatus according to claim 3, wherein said stage includes a fine moving stage, and said supporting member includes a coarse moving stage.

7. A drawing apparatus for performing drawing on a substrate with a charged particle beam, the apparatus comprising a stage apparatus,
said stage apparatus including:
a stage;
a linear motor configured to drive the stage;
a magnetic shield unit configured to surround the linear motor to shield a magnetic field generated by a magnet of the linear motor; and
a degaussing coil located in a space surrounded by the magnetic shield unit and configured to degauss the magnetic shield unit.

8. A method of manufacturing a device, the method comprising:
performing drawing on a substrate with a charged particle beam by using a drawing apparatus;
developing the substrate having undergone drawing; and
processing the developed substrate to manufacture the device,
the drawing apparatus comprising a stage apparatus, and
the stage apparatus including:
a stage;
a linear motor configured to drive the stage;
a magnetic shield unit configured to surround the linear motor to shield a magnetic field generated by a magnet of the linear motor; and
a degaussing coil located in a space surrounded by the magnetic shield unit and configured to degauss the magnetic shield unit.
